(19) United States
(12) Patent Application Publication
(10) Pub. No.: US 2021/0100091 A1
(43) Pub. Date: Apr. 1, 2021

(54) ORGANIC CIRCUIT CARRIER AND APPLICATION THEREOF IN POWER CONVERTERS AND IN VEHICLES

(71) Applicant: Uwe Waltrich, Erlangen (DE)

(72) Inventor: Uwe Waltrich, Erlangen (DE)

(21) Appl. No.: 17/038,040

(22) Filed: Sep. 30, 2020

(30) Foreign Application Priority Data
Sep. 30, 2019 (DE) 10 2019 214 998.7

(51) Int. Cl. H05K 1/02; H05K 1/05; H01L 23/498; B64D 27/24

(52) U.S. Cl. CPC H05K 1/0256; H05K 1/056; B64D 27/24; H01L 23/49838; H01L 23/49894; H05K 1/0209

(57) ABSTRACT

An organic circuit carrier including an organic insulation layer and at least one metallization layer arranged on an upper side, a lower side, or the upper side and the lower side of the organic insulation layer is provided. Side surfaces of the at least one metallization layer are embodied in a convexly curved fashion. A circuit arrangement and a power converter including such an organic circuit carrier are also provided. A vehicle such as an aircraft, including such a power converter, is also provided.

This application claims the benefit of German Patent Application No. DE 10 2019 214 998.7, filed on Sep. 30, 2019, which is hereby incorporated by reference in its entirety.

### FIELD

The present embodiments relate to the partial discharge and dielectric strength of organic circuit carriers in power modules and, more specifically, to an organic circuit carrier, a circuit arrangement including such a circuit carrier, a power converter including a circuit carrier, and a vehicle such as an aircraft, including such a power converter.

### BACKGROUND

Circuit carriers including organic insulation materials have very low thermal conductivities in comparison with inorganic/ceramic materials. In order nevertheless to be able to provide a good cooling link of power semiconductor components of a power module and thus practical use in power modules as main circuit carriers, extremely thin insulation layers (e.g., <100 μm) are therefore used.

This is possible because the organic materials used in the insulation layers have a very high breakdown strength. The minimum insulation layer thickness is limited, however, by the electric field inhomogeneities in the edge region of the metallization circuit carrier. From field theory, the triple point is known as the most critical point in power modules or circuit carriers for excessive field increases.

Triple point denotes the contact point of three materials (e.g., the electrode material, the insulation, and the surrounding medium; an intersection point of substrate metallization, substrate insulator, and potting compound of a power module).

The excessive field increases may lead to partial discharges in the insulation material or in the potting compound of a power module. Partial discharges lead to a degradation of the materials (e.g., as a result of “Electrical Treeing”). As a result of this, the lifetime of the power modules is reduced.

FIG. 1 shows a sectional view of a circuit carrier arrangement of a power module such as is used in power converters, for example. An organic circuit carrier 1 including an insulation layer 1.1 and a metallization layer 1.2 adhesively bonded thereon is seated on a heat sink 2.

The metallization layer 1.2 forms the conductor track(s) of the circuit carrier 1 and is composed of copper, for example. The insulation layer 1.1 may be composed of polymide. The power electronic semiconductor component 4 is electrically connected to the metallization layer 1.2 by a connection layer 3. Further electrical connections are effected by the wire bonds 5.

A triple point 6, as described above, forms at the boundary between insulation layer 1.1, metallization layer 1.2, and the surroundings, and critical excessive electric field increases may occur at the triple point.

Since the electric field strength is a function of the layer thickness of the insulation material, thick insulation materials are used as a remedy in the prior art in order to reduce the field strength in the region of the triple point. However, this leads to a more than proportional increase in the thermal resistance, since the field strength increases nonlinearly in the region of the triple point.

A remedy may also be provided by reducing the maximum permissible operating voltage of power modules. However, that is generally not desired.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a solution that lengthens the lifetime of electrical power modules including power semiconductor components on organic circuit carrier boards and minimizes an insulation layer thickness necessary owing to electrical requirements and also the thermal resistance is provided to avoid disadvantages mentioned above.

One aspect of the present embodiments includes homogeneously decreasing a field strength by a geometric adaptation (e.g., “geometric field control”) of metallization sidewalls of substrate metallization, with the result that at a triple point, the field strength is reduced by comparison with the prior art.

In contrast to ceramic insulation carriers in which the metallizations are etched, the metallizations are applied by adhesive bonding in the case of the novel organic insulation carriers. As a result, it the form of the metallization sidewall may be fashioned highly precisely and freely.

From high-voltage technology, besides circle-segment-shaped profiles, two further sidewall profiles (e.g., the Borda profile and the Rogowski profile) are also known, which may be used to avoid excessive field increases at such edge structures.

Further, it is known that a ratio of the relative permittivity of both insulation materials (e.g., insulation film and potting compound) likewise influences field strengths in a critical region (e.g., “refractive field control”). A ratio of the relative permittivity of the insulating film to the relative permittivity of the potting compound of less than or equal to one may be provided.

Since polyimide-based films are often used here, an edge region of the organic circuit carrier in the module may additionally be filled with polyimide. This has the following advantages with regard to field loading (e.g., any other insulation material may be mentioned here instead of polyimide). The triple points shift. A distance between the triple points increases with respect to one another, and a field loading thus decreases at this point. Using the local potting with the same insulation material, the ratio of the relative permittivities in the critical region of the edge geometry becomes equal to one and is thus improved by comparison with the prior art. The field strength may be decreased laterally by the suitable choice of the metallization profile (e.g., Rogowski and Borda profile).

The present embodiments include an organic circuit carrier (e.g., a DCB substrate) including an organic insulation layer and including at least one metallization layer arranged on the upper and/or the lower side of the insulation layer. The side surfaces of the metallization layer are embodied in a convexly curved fashion. In one embodiment, the metallization layer is smaller than the insulation layer, such that the metallization sidewall of the metallization is completely surrounded by the insulation layer.

A layer may be a mass of a substance or the like spread areally over, under, or between something else. The insulation layer may be an insulation film, for example, composed of polyimide. The metallization layer forms the electrical conductor tracks of the circuit carrier. The side surfaces of the metallization layer may also be referred to as edge or metallization sidewall.

In one development, the profile of the convex curvature of the side surfaces may correspond to a circular function, a Borda function, or a Rogowski function.

In a further embodiment, the metallization layer may be surrounded up to a height of a surface of the metallization layer by a second potting compound. The second potting compound is formed from the same material as the insulation layer. The number of triple points may be reduced as a result.

The present embodiments also include a circuit arrangement including at least one organic circuit carrier according to the present embodiments. The circuit arrangement includes at least one semiconductor component arranged on the metallization layer (e.g., a power semiconductor switch), and a heat sink, on which the organic circuit carrier is arranged.

The present embodiments also include a power converter (e.g., an inverter) including a circuit arrangement according to the present embodiments.

Inverter denotes a power converter that generates an AC voltage from a DC voltage; a frequency and an amplitude of the AC voltage is varied. An output AC voltage is generated from an input DC voltage by a DC voltage link and clocked semiconductor switches.

The present embodiments include a vehicle (e.g., an aircraft) including a power converter according to the present embodiments for an electric or hybrid electric drive.

Vehicle may be any type of locomotion or transport, whether manned or unmanned. An aircraft is a flying vehicle.

In a further embodiment, the vehicle includes an electric motor supplied with electrical energy by the power converter, and a propeller enabled to rotate by the electric motor.

The present embodiments also include a method for producing an organic circuit carrier. The method includes providing an organic insulation layer, providing at least one metallization layer, processing the side surfaces of the metallization layer such that the side surfaces of the metallization layer are convexly curved, and adhesively bonding the metallization layer onto the top side or underside of the insulation layer.

Further special features and advantages of the invention will become clear from the following explanations of exemplary embodiments with reference to schematic drawings.

### BRIEF DESCRIPTION OF THE DRAWINGS

FIG. 1 shows a sectional view through a power module in accordance with the prior art;

FIG. 2 shows a sectional view through one embodiment of a circuit carrier;

FIG. 3 shows a sectional view through one embodiment of a power module;

FIG. 4 shows a sectional view through a another embodiment of a power module;

FIG. 5 shows a plan view of one embodiment of a power module;

FIG. 6 shows a block diagram of one embodiment of a power converter;

and

FIG. 7 shows one embodiment of an aircraft including a power converter.

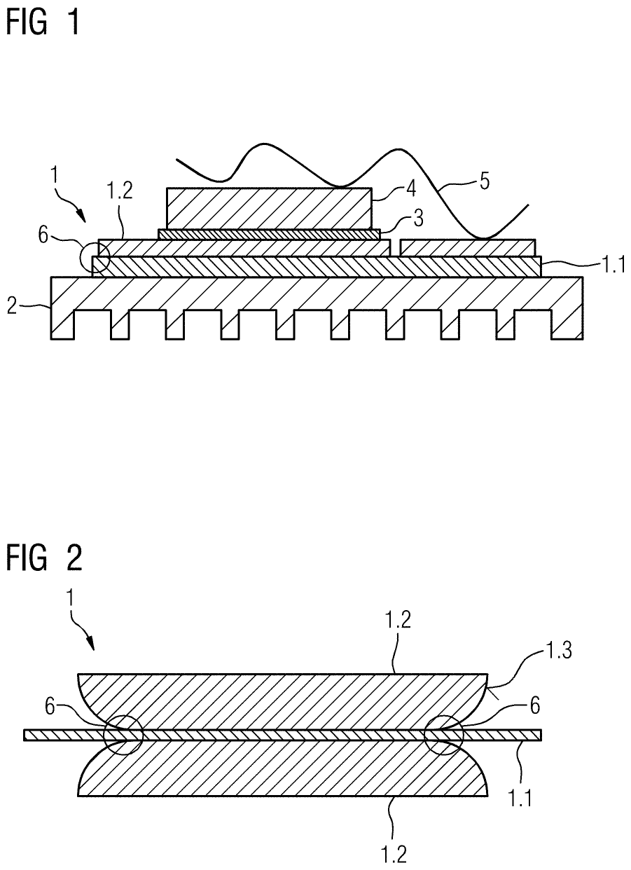

### DETAILED DESCRIPTION

FIG. 2 shows a sectional view through one embodiment of a circuit carrier 1. The circuit carrier 1 includes an insulation layer 1.1. A respective metallization layer 1.2 is adhesively bonded onto a top side and an underside of the insulation layer. The insulation layer 1.1 is a polyimide film, for example; the metallization layer is composed of copper, for example. According to the present embodiments, side surfaces 1.3 (e.g., sidewalls) of the metallization layer 1.2 are embodied in a convexly curved fashion. The metallization layer 1.2 is embodied such that the metallization layer 1.2 is smaller than the insulation layer 1.1 in terms of an areal extent.

In one embodiment, profile forms may be circular functions or Rogowski and Borda functions. As a result of the convex fashioning of the side surfaces 1.3, an excessive field increase at triple points 6 is reduced by comparison with the prior art.

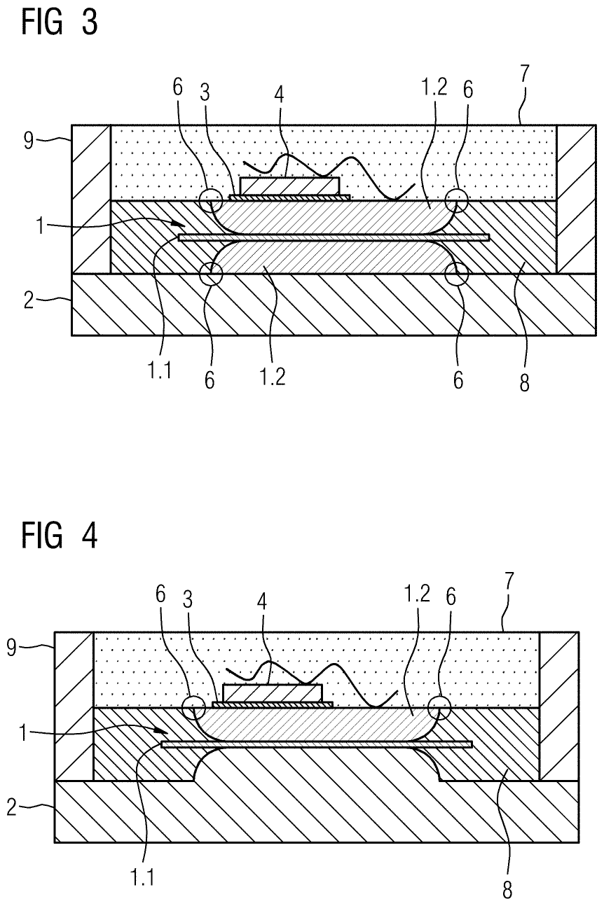

FIG. 3 shows a sectional view of one embodiment of a power module including a housing 9 on a heat sink 2. Within the housing 9, the organic circuit carrier 1 is seated on the heat sink 2. A semiconductor component 4 is arranged on the organic circuit carrier with the aid of a connection layer 3. The organic circuit carrier 1 consists of an insulation layer 1.1. and metallization layers 1.2 adhesively bonded on both sides. The side surfaces of the metallization layers are embodied in a convexly curved fashion in accordance with the illustration in FIG. 2.

In the upper region, the power module is filled with a soft first potting compound 7. The power module is filled with a second potting compound 8 up to the level of the connection layer 3. The second potting compound 8 is composed of the same material as the insulation layer 1.1. The spatial distance between adjacent triple points 6 is increased as a result.

FIG. 4 shows a cross-sectional view of a power module in a modified form by comparison with the circuit arrangement according to FIG. 3. The underside metallization layer 1.2 of the circuit carrier 1 is omitted in this case. The circuit carrier is adhesively bonded directly onto the heat sink 2. As a result, by comparison with the arrangement in FIG. 3, two triple points 6 are omitted, such that only two triple points 6 are still present in this view. Here, too, the second potting compound 8 consists of the same material as the insulation layer 1.1 of the circuit carrier 1.

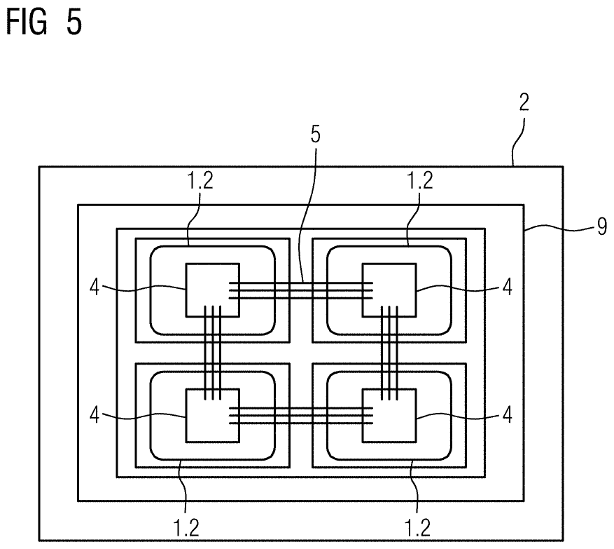

FIG. 5 shows a plan view of a power module including four circuit carriers 1 (e.g., “island substrate”), each equipped with a semiconductor component 4. Each of the four circuit carriers 1 exhibits a construction as illustrated in FIG. 3. All the circuit carriers 1 are arranged in a common housing 9 and arranged on a heat sink 2. The electrical connections are effected by the wire bonds 5.

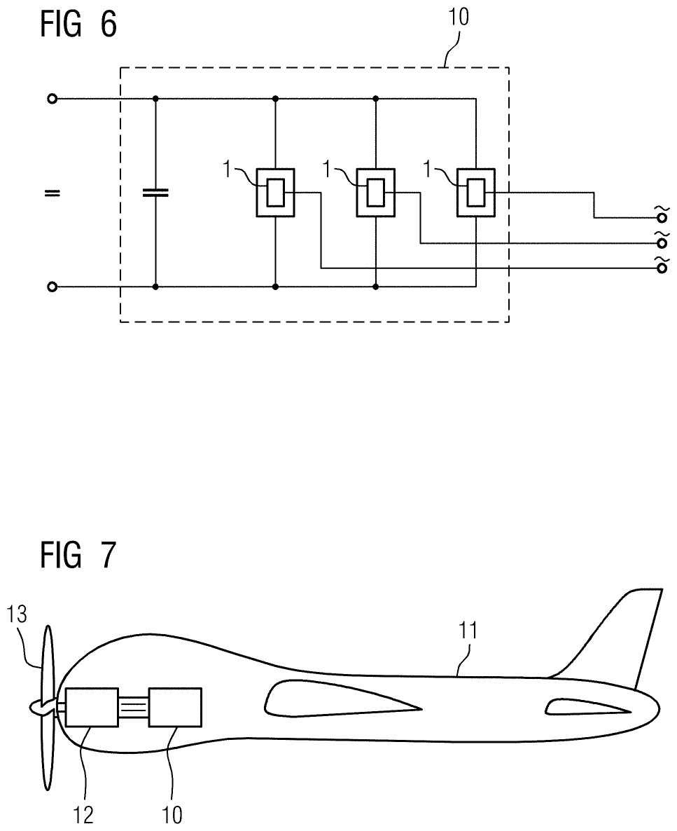

FIG. 6 shows a block circuit diagram of a DC/AC power converter 10 (e.g., of an inverter) including a circuit arrangement for generating a three-phase AC voltage. Each phase of the circuit arrangement has, in each case, at least one circuit carrier 1 according to the present embodiments.

FIG. 7 shows an electric or hybrid electric aircraft 11 (e.g., an airplane) including a power converter 10 in accordance with FIG. 6, which supplies an electric motor 12 with electrical energy. The electric motor 12 drives a propeller 13. Both are part of an electrical thrust generating unit. A power converter 10 may also be part of an on-board electrical system.

Although the invention has been described and illustrated more specifically in detail by the exemplary embodiments, the invention is not restricted by the disclosed examples, and other variations may be derived therefrom by a person skilled in the art without departing from the scope of protection of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. An organic circuit carrier comprising:
an organic insulation layer; and
at least one metallization layer arranged on an upper side, a lower side, or the upper side and the lower side of the organic insulation layer,
wherein side surfaces of the at least one metallization layer are configured in a convexly curved fashion.

2. The organic circuit carrier of claim 1, wherein a profile of the convex curvature of the side surfaces corresponds to a circular function.

3. The organic circuit carrier of claim 1, wherein a profile of the convex curvature of the side surfaces corresponds to a Borda and Rogowski function.

4. The organic circuit carrier of claim 1, wherein the at least one metallization layer is surrounded up to a height of a surface of the at least one metallization layer by a potting compound that is formed from a same material as the organic insulation layer.

5. The organic circuit carrier of claim 1, wherein the at least one metallization layer is attached to the upper side, the lower side, or the upper side and the lower side of the organic insulation layer with an adhesive.

6. A circuit arrangement comprising:
an organic circuit carrier comprising:
an organic insulation layer; and
at least one metallization layer arranged on an upper side, a lower side, or the upper side and the lower side of the organic insulation layer, wherein side surfaces of the at least one metallization layer are configured in a convexly curved fashion;
at least one semiconductor component arranged on the at least one metallization layer; and
a heat sink, on which the organic circuit carrier is arranged.

7. The circuit arrangement of claim 6, wherein a profile of the convex curvature of the side surfaces corresponds to a circular function.

8. The circuit arrangement of claim 7, wherein a profile of the convex curvature of the side surfaces corresponds to a Borda and Rogowski function.

9. The circuit arrangement of claim 7, wherein the at least one metallization layer is surrounded up to a height of a surface of the at least one metallization layer by a potting compound that is formed from a same material as the organic insulation layer.

10. The circuit arrangement of claim 6, wherein the at least one metallization layer is attached to the upper side, the lower side, or the upper side and the lower side of the organic insulation layer with an adhesive.

11. A power converter comprising:
a circuit arrangement comprising:
an organic circuit carrier comprising:
an organic insulation layer; and
at least one metallization layer arranged on an upper side, a lower side, or the upper side and the lower side of the organic insulation layer, wherein side surfaces of the at least one metallization layer are configured in a convexly curved fashion;
at least one semiconductor component arranged on the at least one metallization layer; and
a heat sink, on which the organic circuit carrier is arranged.

12. The power converter of claim 11, wherein the power converter is an inverter.

13. The power converter of claim 11, wherein a profile of the convex curvature of the side surfaces corresponds to a circular function.

14. The power converter of claim 11, wherein a profile of the convex curvature of the side surfaces corresponds to a Borda and Rogowski function.

15. The power converter of claim 11, wherein the at least one metallization layer is surrounded up to a height of a surface of the at least one metallization layer by a potting compound that is formed from a same material as the organic insulation layer.

16. The power converter of claim 11, wherein the at least one metallization layer is attached to the upper side, the lower side, or the upper side and the lower side of the organic insulation layer with an adhesive.
